(19) United States
(12) Patent Application Publication
(10) Pub. No.: US 2018/0142359 A1
(43) Pub. Date: May 24, 2018

(54) COPPER PROCESS DEVICE WITH EXPLOSION-PROOF FUNCTION AND COPPER PROCESS EXPLOSION-PROOF METHOD

(71) Applicant: Shenzhen China Star Optoelectronics Technology Co., Ltd., Shenzhen (CN)

(72) Inventor: Jia LI, Shenzhen (CN)

(73) Assignee: Shenzhen China Star Optoelectronics Technology Co., Ltd., Shenzhen (CN)

(21) Appl. No.: 15/128,967

(22) PCT Filed: May 12, 2016
(86) PCT No.: PCT/CN2016/081786

§ 371 Date: Sep. 24, 2016

(30) Foreign Application Priority Data
Mar. 18, 2016 (CN) 201610159171.8

(51) Int. Cl. C23F 1/18; H01L 21/67

(52) U.S. Cl. CPC C23F 1/18; G02F 1/1303; H01L 21/67248; H01L 21/6708

(57) ABSTRACT

A copper process device with an explosion-proof function and a copper process explosion-proof method, the copper process device including a reaction chamber, a container provided below the reaction chamber for containing a solution for etching, a liquid inlet tube, a reflux tube, a temperature control unit, an automatic control unit and a pump on the liquid inlet tube. The reaction chamber is provided with a spray component for spraying the solution to a substrate therein, the liquid inlet tube is used for deliver the solution from the container to the spray component. The temperature control unit includes a temperature sensor for detecting a temperature of the solution within the container. The automatic control unit is electrically connected with the temperature control unit, and controls the pump to stop working when the temperature of the solution in the container is higher than a predetermined temperature range.

### BACKGROUND OF THE INVENTION

### 1. Field of the Invention

The present disclosure relates to the technical field of liquid crystal display manufacturing, and more particularly, to a copper process device with an explosion-proof function and a copper process explosion-proof method.

### 2. The Related Arts

As the TFT-LCD (thin film transistor-liquid crystal display) is developing towards extra large size, high driving frequency and high resolution, the way to effectively reduce the wire resistance and stray capacitance of the panel has become the major issue. When manufacturing a thin film transistor liquid crystal display, an advanced wire process technology has become a decisive factor for characteristics of a thin film transistor component and a panel.

In a TFT, a Cu, instead of Al, process has been widely applied on large panels due to its low resistance and high frequency. A Cu metal is normally etched by using hydrogen peroxide, but the hydrogen peroxide is very unstable, and as the concentration of Cu ions in the etching solution increases, the decomposition of the hydrogen peroxide will become faster, thereby generating a large quantity of heat and gas during a short time period, which may cause potential safety problem such as explosion of the container and bring hidden dangers to safety production.

### SUMMARY

To solve the problem of the prior art, the present disclosure provides a safe and reliable copper process device with explosion-proof function and an explosion-proof method.

In order to achieve the above purpose, the technical solution applied in the present disclosure is as follows:

A copper process device with explosion-proof function includes a reaction chamber, a container provided below the reaction chamber for containing a solution for etching, a liquid inlet tube, a reflux tube, a temperature control unit, an automatic control unit and a pump on the liquid inlet tube. The reaction chamber is provide with a spray component for spraying the solution to a substrate therein, the liquid inlet tube is connected between the spray component and the container, the reflux tube is connected between a bottom of the reaction chamber and the container, and the liquid inlet tube is used for transferring the solution from the container to the spray component under the work of the pump. The temperature control unit includes a temperature sensor provided in the container for detecting a temperature of the solution within the container in real time. The automatic control unit is electrically connected with the temperature control unit, and controls the pump to stop working when the temperature of the solution in the container is higher than a predetermined temperature range.

Furthermore, the copper process device with explosion-proof function further includes an over temperature alarm module which is connected to the automatic control unit. The over temperature alarm module issues an alarm information when the temperature of the solution within the container is higher than a predetermined temperature range.

Furthermore, the temperature control unit further includes a heater for heating the solution within the container when the temperature thereof is lower than a predetermined temperature range until the solution reaches the predetermined temperature range.

Furthermore, the copper process device with explosion-proof function further includes a water discharge tube connected to the container, and the automatic control unit controls the water discharge tube to initiate liquid discharge when the temperature of the solution within the container is higher than a predetermined temperature range.

Furthermore, the copper process device with explosion-proof function further includes a circulation tube with both ends connected to two parts having different heights of the container and a circulation pump provided on the circulation tube and transferring the solution from a lower orifice of the circulation tube to another orifice.

Furthermore, the copper process device with explosion-proof function further includes a dilution tube connected to the container, and the automatic control unit controls the dilution tube to initiate water inlet to dilute the solution when the temperature of the solution within the container is higher than a predetermined temperature range.

Another purpose of the present disclosure lies in providing a copper process explosion-proof method, wherein a temperature control unit detects a temperature of a solution within a container and an automatic control unit controls a pump to stop working when the temperature of the solution within the container is higher than a predetermined temperature range, meanwhile, the solution within a reaction chamber flows back to the container below the reaction chamber from a reflux tube due to force of gravity.

Furthermore, the copper process explosion-proof method further comprises: when the temperature of the solution in the container is lower than a predetermined temperature range, the automatic control unit controls the temperature control unit to heat the solution within the container, until the solution reaches the predetermined temperature range.

Furthermore, the copper process explosion-proof method further comprises: when the temperature of the solution in the container is higher than a predetermined temperature range, the automatic control unit controls the dilution tube to inject water to the container, until the solution reaches the predetermined temperature range.

Furthermore, the copper process explosion-proof method further comprises: when the temperature of the solution within the container is higher than a predetermined temperature range, the automatic control unit controls the water discharge tube to initiate liquid discharge, until the solution is lower than a predetermined liquid level, and an amount of water intake from the dilution tube is smaller than an amount of water discharge to the water discharge tube per unit time.

The present disclosure uses the temperature control unit to monitor the temperature of the container for containing the solution in real time, and secures the solution within the container at a normal temperature by using the automatic control unit to control a coordination of corresponding structures of the device when the temperature of the solution is abnormal. The temperature control unit can be controlled to perform heating when the temperature of the solution is too low, the over temperature alarm module can be controlled to issue an alarm when the temperature of the solution is too high, and a supply of solution to the reaction chamber can be cut off in order to prevent damage of the substrate. In addition, the temperature of the solution within the container can be reduced by controlling the work of the dilution tube, and the diluted solution is discharged through the water discharge tube. The copper process device and the copper process explosion-proof method may ensure smooth proceeding of the copper process, and may avoid an explosion of the container caused by an unstable reaction of the solution, thereby ensuring the security of operatives.

### BRIEF DESCRIPTION OF THE DRAWINGS

FIG. 1 is a schematic diagram showing a structure of a copper process device according to an embodiment of the present disclosure.

FIG. 2 is a block diagram showing a principle of a copper process explosion-proof structure according to an embodiment of the present disclosure.

FIG. 3 is a diagram showing a principle of a copper process explosion-proof method according to an embodiment of the present disclosure.

### DETAILED DESCRIPTION OF THE PREFERRED EMBODIMENTS

In order to make purposes, technical solutions and advantages of the present disclosure clear and apparent, the present disclosure will be detailed explained by referring to the figures and using exemplary embodiments. It should be understood that the specific embodiments described here are only used for interpreting the present disclosure, rather than defining the present disclosure.

Referring to FIG. 1, a copper process device with explosion-proof function according to an embodiment of the present disclosure includes a reaction chamber 10 for receiving a substrate S to perform a reaction process and a container 20 provided below the reaction chamber 10. A spray component 11 is provided in the reaction chamber 10 for spraying a solution for etching to the substrate S therein, a liquid inlet tube 30 is connected between the spray component 11 and the container 20, and a reflux tube 40 is connected between a bottom of the reaction chamber 10 and the container 20. The container 20 is used for containing the solution, and the liquid inlet tube 30 is connected with a pump M thereon. When the pump M is working, the solution within the container 20 is extracted by the liquid inlet tube 30 to enter into the spray component 11 in the reaction chamber 10 and is sprayed toward the substrate S, and after the etching reaction, the solution flows back into the container 20 through the reflux tube 40 at the bottom of the reaction chamber 10 for reutilization and the cycle repeats.

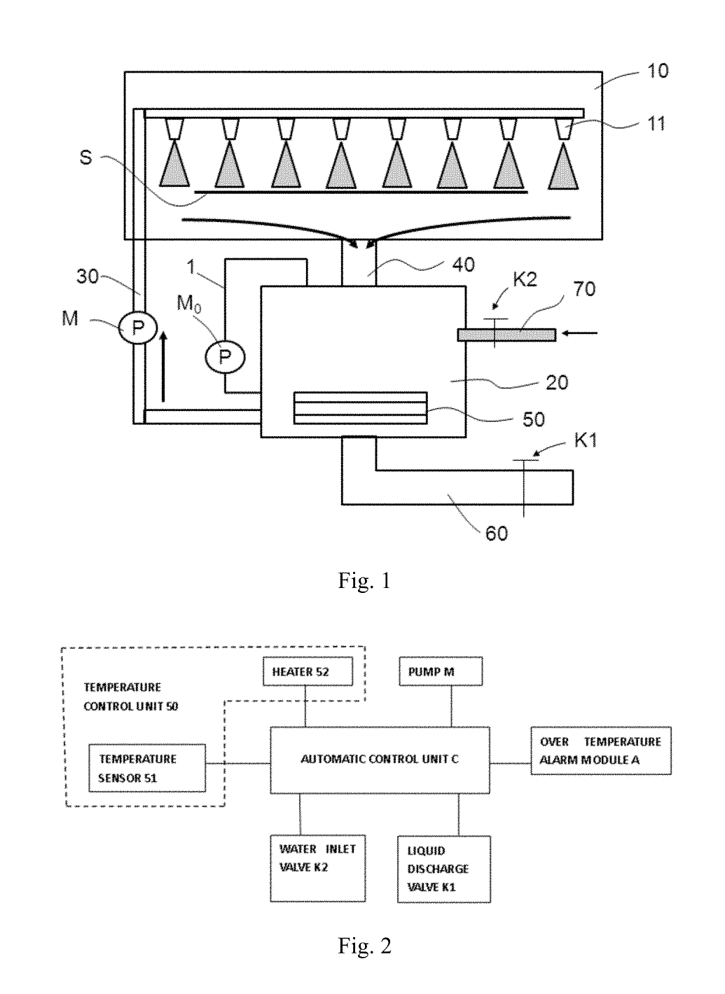

However, a decomposition of the solution tends to generate a large quantity of gas and heat after the etching reaction, in order to avoid explosion of the container 20 caused by excessive high temperature of the liquid flowing back to the container 20 through the reflux tube 40, a structure of an explosion-proof portion of the copper process device according to an embodiment of the present disclosure includes a temperature control unit 50 and an automatic control unit C electrically connected to each other, as shown in FIG. 2. The temperature control unit 50 includes a temperature sensor 51 provided in the container 20 for detecting a temperature of the solution within the container 20 in real time. The automatic control unit C controls the pump M to stop working when the temperature of the solution within the container 20 is higher than a predetermined temperature range T₀. After the pump M stops working, the liquid inlet tube 30 stops delivering the solution, and the solution in the liquid inlet tube 30 completely flows back to the container 20 due to the force of gravity, so as to prevent accelerating the decomposition of the solution caused by further reaction between the solution and the copper substrate S, thereby avoiding an accident. For example, the predetermined temperature range T₀ can be set below an explosion limit temperature, and a cushion time can be reserved so that a pre-warning can be generated to cut off the solution supply of the process before the temperature of the solution within the container 20 reaches the explosion limit temperature, in order to prevent the accident from happening.

Specifically, the copper process device further includes a circulation tube 1 and a circulation pump M₀. Both ends of the circulation tube 1 are connected to two parts of the container 20 having different heights, and the circulation pump M₀ is provided on the circulation tube 1 and transfers the solution from a lower orifice to another orifice of the circulation tube 1. Preferably, an end of the circulation tube 1 is provided on a side wall of the container 20, and the other end thereof is provided on a top wall of the container 20. The solution is extracted from the bottom to the top, and flows back from the top to the bottom, thereby mixing the solution thoroughly and achieving heat uniformity of the cold solution and hot solution.

Meanwhile, an over temperature alarm module can further be connected on the automatic control unit C in the copper process device of the present embodiment, and the automatic control unit C feeds information back to the over temperature alarm module so that the over temperature alarm module may issue an alarm information when the temperature of the solution within the container 20 is higher than the predetermined temperature range T₀, so as to alarm the operator to take some protective actions.

In view of the optimal reaction temperature of the solution, the temperature control unit 50 can be further provided with a heater for heating the solution in the container 20 when the temperature of the solution within the container 20 is lower than the predetermined temperature range T₀. The heater can heat the solution within the container 20 until the solution reaches the predetermined temperature range T₀ (i.e., the heater will stop heating automatically when the solution reaches the predetermined temperature range T₀).

Furthermore, a water discharge tube 60 is further connected to an end of the container 20 of the copper process device according to the present embodiment. The water discharge tube 60 has a liquid discharge valve K1 provided thereon. The pump M stops working when the temperature of the solution within the container 20 is higher than the predetermined temperature range T₀, and the solution completely flows back to the container 20 due to the force of gravity. The automatic control unit C controls the water discharge tube 60 to initiate liquid discharge so as to discharge the high temperature solution. The water discharge tube 60 is preferably provided at the bottom of the container 20 so that the solution within the container 20 may be discharged to reach any required liquid level.

As an implementation of the present embodiment, the copper process device further includes a dilution tube 70 connected to the container 20. A water inlet valve K2 is provided on the dilution tube 70. When the temperature of the solution in the container 20 is higher than the predetermined temperature range T₀, the automatic control unit C controls the dilution tube 70 to initiate water inlet to dilute the solution, upon the solution within the container 20 reaches the predetermined temperature range T₀, the water inlet valve K2 is automatically cut off. The dilution injected via the dilution tube 70 adopts the DIW (De-Ion water) for diluting and cooling, which can prevent the foreign matter from affecting the solution to the maximum extent. An amount of water intake from the dilution tube 70 is smaller than an amount of liquid discharge to the water discharge tube per unit time, thereby ensuring that the solution in the container will not overflow during the process of diluting and cooling.

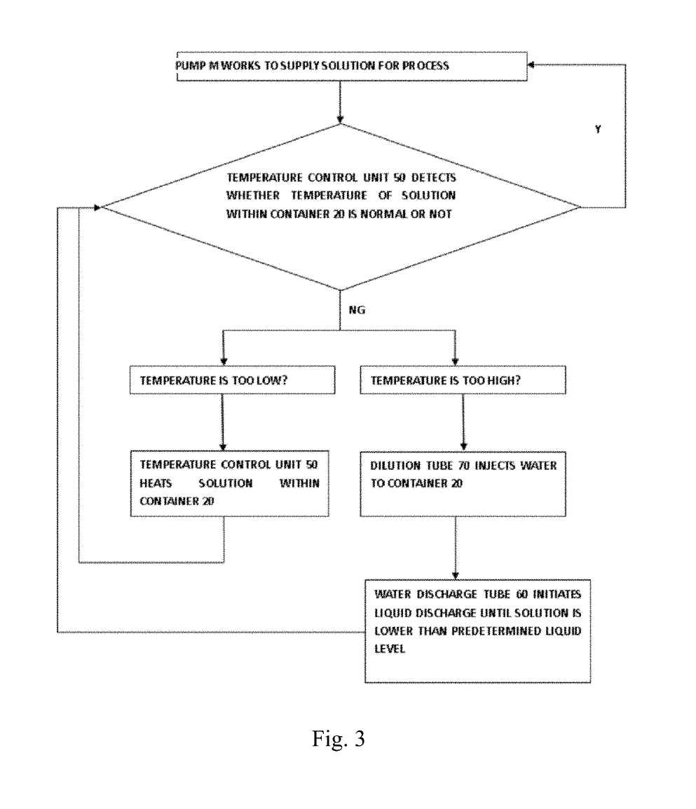

The present embodiment also provides a copper process explosion-proof method, as shown in FIG. 3, in normal status, the pump M works, and the solution is extracted by the liquid inlet tube 30 to enter the spray component 11 in the reaction chamber 10 and is sprayed to the substrate S. After the etching reaction, the solution flows into the container 20 through the reflux tube 40 at the bottom of the reaction chamber 10 for reutilization. Meanwhile, the circulation pump M₀ delivers solution from a lower orifice of the circulation tube 1 to another orifice. The temperature control unit 50 detects whether the temperature of the solution within the container 20 is anomalous in real time (i.e. whether the temperature is within the predetermined temperature range T₀). The automatic control unit C controls the pump M to stop working when the temperature of the solution within the container 20 is higher than the predetermined temperature range T₀, meanwhile, the solution within the reaction chamber 10 flows back to the container 20 provided below the reaction chamber 10 through the reflux tube 40 due to the force of gravity, and the delivery of the solution in the liquid inlet tube 30 is stopped.

The copper process explosion-proof method further comprises: the automatic control unit C controls the dilution tube 50 to heat the solution within the container 20 when the temperature of the solution within the container 20 is too low (lower than a predetermined temperature range T₀), until the solution reaches the predetermined temperature range T₀.

When the temperature of the solution within the container 20 is higher than the predetermined temperature range T₀, the copper process explosion-proof method further comprises: the automatic control unit C controls the dilution tube 70 to inject water into the container 20 until the solution reaches the predetermined temperature range T₀.

When the temperature of the solution within the container 20 is higher than the predetermined temperature range T₀, the copper process explosion-proof method further comprises: the automatic control unit C controls the water discharge tube 60 to initiate liquid discharge, until the solution is lower than the predetermined liquid level, and the amount of the water intake from the dilution tube 70 is preferably smaller than the amount of the liquid discharge to the water discharge tube 60 per unit time.

The present disclosure uses the temperature control unit to monitor the temperature of the container for containing the solution in real time, and uses the automatic control unit to control the coordination of corresponding structures of the device when the temperature of the solution is anomalous, in order to maintain a normal temperature of the solution within the container. The temperature control unit can be controlled to perform heating when the temperature of the solution is too low. The over temperature alarm module can be controlled to issue an alarm when the temperature of the solution is too high, and a supply of solution to the reaction chamber can be cut off in order to prevent damage of the substrate. In addition, the temperature of the solution within the container can be reduced by controlling the work of the dilution tube, and the diluted solution is discharged through the water discharge tube. The copper process device and the copper process explosion-proof method may ensure smooth proceeding of the copper process, and may avoid explosion of the container caused by unstable reaction of the solution, thereby ensuring the security of operatives.

The above statements are only the specific embodiments of the present application, it should be pointed out that, to those ordinary skilled in the art, several improvements and polish can be made without breaking away from the principle of the present application, also those improvements and polish should be considered as the protection scope of the present application.

What is claimed is:

1. A copper process device with explosion-proof function comprising: a reaction chamber, a container provided below the reaction chamber for containing a solution for etching, a liquid inlet tube, a reflux tube, a temperature control unit, an automatic control unit and a pump on the liquid inlet tube, wherein the reaction chamber is provided with a spray component for spraying the solution to a substrate therein, the liquid inlet tube is connected between the spray component and the container, the reflux tube is connected between a bottom of the reaction chamber and the container, and the liquid inlet tube is used for deliver the solution from the container to the spray component when the pump is working; wherein the temperature control unit includes a temperature sensor provided in the container and used for detecting a temperature of the solution within the container in real time; and wherein the automatic control unit is electrically connected with the temperature control unit and controls the pump to stop working when the temperature of the solution within the container is higher than a predetermined temperature range.

2. The copper process device with explosion-proof function of claim 1, further comprising an over temperature alarm module which is connected to the automatic control unit, wherein the over temperature alarm module issues alarm information when the temperature of the solution in the container is higher than the predetermined temperature range.

3. The copper process device with explosion-proof function of claim 1, wherein the temperature control unit further includes a heater used for heating the solution within the container when the temperature of the solution in the container is lower than the predetermined temperature range, until the solution reaches the predetermined temperature range.

4. The copper process device with explosion-proof function of claim 1, further comprising a water discharge tube connected to the container, and the automatic control unit controls the water discharge tube to initiate liquid discharge when the temperature of the solution within the container is higher than the predetermined temperature range.

5. The copper process device with explosion-proof function of claim 1, further comprising a circulation tube with both ends connected to two parts of the container having different heights and a circulation pump provided on the circulation tube and transferring the solution from a lower orifice of the circulation tube to another orifice.

6. The copper process device with explosion-proof function of claim 1, further comprising a dilution tube connected to the container, and the automatic control unit controls the dilution tube to initiate water inlet to dilute the solution when the temperature of the solution within the container is higher than the predetermined temperature range.

7. The copper process device with explosion-proof function of claim 2, further comprising a dilution tube connected to the container, and the automatic control unit controls the dilution tube to initiate water inlet to dilute the solution when the temperature of the solution within the container is higher than the predetermined temperature range.

8. The copper process device with explosion-proof function of claim 3, further comprising a dilution tube connected to the container, and the automatic control unit controls the dilution tube to initiate water inlet to dilute the solution when the temperature of the solution within the container is higher than the predetermined temperature range.

9. The copper process device with explosion-proof function of claim 4, further comprising a dilution tube connected to the container, and the automatic control unit controls the dilution tube to initiate water inlet to dilute the solution when the temperature of the solution within the container is higher than the predetermined temperature range.

10. The copper process device with explosion-proof function of claim 5, further comprising a dilution tube connected to the container, and the automatic control unit controls the dilution tube to initiate water inlet to dilute the solution when the temperature of the solution within the container is higher than the predetermined temperature range.

11. A copper process explosion-proof method, wherein the temperature control unit detects the temperature of the solution within the container, and the automatic control unit controls the pump to stop working when the temperature of the solution in the container is higher than a predetermined temperature range, meanwhile, the solution within the reaction chamber flows back to the container provided below the reaction chamber through the reflux tube due to the force of gravity.

12. The copper process explosion-proof method of claim 11, further comprising: the automatic control unit controls the temperature control unit to heat the solution within the container when the temperature of the solution within the container is lower than the predetermined temperature range, until the solution reaches the predetermined temperature range.

13. The copper process explosion-proof method of claim 11, further comprising: the automatic control unit controls the dilution tube to inject water to the container when the temperature of the solution within the container is higher than the predetermined temperature range, until the solution reaches the predetermined temperature range.

14. The copper process explosion-proof method of claim 13, further comprising: when the temperature of the solution within the container is higher than the predetermined temperature range, the automatic control unit controls the water discharge tube to initiate liquid discharge, until the solution is lower than a predetermined liquid level, and an amount of water intake from the dilution tube is smaller than an amount of liquid discharge to the water discharge tube per unit time.

15. The copper process explosion-proof method of claim 12, further comprising: the automatic control unit controls the dilution tube to inject water to the container when the temperature of the solution within the container is higher than the predetermined temperature range, until the solution reaches the predetermined temperature range.

16. The copper process explosion-proof method of claim 15, further comprising: when the temperature of the solution within the container is higher than the predetermined temperature range, the automatic control unit controls the water discharge tube to initiate liquid discharge, until the solution is lower than a predetermined liquid level, and an amount of water intake from the dilution tube is smaller than an amount of liquid discharge to the water discharge tube per unit time.
